(19) United States
(12) Patent Application Publication
(10) Pub. No.: US 2026/0304847 A1
(43) Pub. Date: Oct. 1, 2026

(54) SEMICONDUCTOR DEVICE

(71) Applicant: SK hynix Inc., Gyeonggi-do (KR)

(72) Inventors: Yu Jin KIM, Gyeonggi-do (KR); Se Hun KANG, Gyeonggi-do (KR); Ki Vin IM, Gyeonggi-do (KR); Nam Gue LEE, Gyeonggi-do (KR)

(21) Appl. No.: 19/347,722

(22) Filed: Oct. 2, 2025

(30) Foreign Application Priority Data
Mar. 31, 2025 (KR) 10-2025-0041143

(51) Int. Cl. H10D 30/69; H10D 62/40; H10D 64/68; H10B 51/30; H10D 30/01; H10D 64/01

(52) U.S. Cl. CPC H10D 30/701; H10D 62/40; H10D 64/689; H10B 51/30; H10D 30/0415; H10D 64/033

(57) ABSTRACT

According to embodiments of the present disclosure, a semiconductor device includes a first electrode and a second electrode, and a dielectric layer disposed between the first electrode and the second electrode. The dielectric layer includes a first ferroelectric layer; a second ferroelectric layer disposed between the first ferroelectric layer and the second electrode and having a domain different from a domain of the first ferroelectric layer; and a domain separation layer disposed between the first ferroelectric layer and the second ferroelectric layer and containing a first dopant and a metal element. The first dopant includes a metal cation having a valency different from a valency of the metal element.

### CROSS-REFERENCES TO RELATED APPLICATION

The present application claims priority under 35 U.S.C. 119(a) to Korean patent application number 10-2025-0041143 filed on Mar. 31, 2025, which is incorporated herein by reference in its entirety.

### BACKGROUND

### 1. Technical Field

Embodiments of the present disclosure relate to a semiconductor device.

### 2. Related Art

Due to characteristics such as miniaturization, multifunctionality, and/or low manufacturing cost, semiconductor devices are gaining attention as important components in the electronics industry. As the electronics industry advances significantly, semiconductor devices are becoming increasingly highly integrated. As semiconductor devices become more highly integrated, the number of unit elements such as capacitors arranged within the semiconductor devices increases. Accordingly, maintaining the characteristics of such unit elements in a stable manner faces increasing technical challenges.

### SUMMARY

According to embodiments of the present disclosure, a semiconductor device capable of minimizing degradation of the semiconductor device caused by repetitive switching operations may be provided.

The objects of the embodiments of the present disclosure are not limited to those mentioned herein, and other objects not explicitly described may be clearly understood by those skilled in the art from the following description.

Embodiments of the present disclosure may provide a semiconductor device including a first electrode and a second electrode, and a dielectric layer disposed between the first electrode and the second electrode. The dielectric layer may include a first ferroelectric layer, a second ferroelectric layer disposed between the first ferroelectric layer and the second electrode and having a domain different from a domain of the first ferroelectric layer, and a domain separation layer disposed between the first ferroelectric layer and the second ferroelectric layer and containing a first dopant and a metal element. The first dopant may include a metal cation having a valency different from a valency of the metal element.

Embodiments of the present disclosure may provide a semiconductor device including a substrate including an active region, a lower electrode contact plug connected to the active region, a lower electrode connected to the lower electrode contact plug, an upper electrode disposed over the lower electrode, and a dielectric layer disposed between the lower electrode and the upper electrode. The dielectric layer may include a first ferroelectric layer, a second ferroelectric layer disposed between the first ferroelectric layer and the upper electrode and having a domain different from a domain of the first ferroelectric layer, and a domain separation layer disposed between the first ferroelectric layer and the second ferroelectric layer and containing a first dopant and a metal element. The first dopant may include a metal cation having a valency different from a valency of the metal element.

According to embodiments of the present disclosure, a semiconductor device can minimize degradation of the device characteristics caused by repeated switching operations.

The effects of the embodiments of the present disclosure are not limited to those described above, and other effects not explicitly mentioned may be clearly understood by those skilled in the art based on the description of the claims.

### BRIEF DESCRIPTION OF THE DRAWINGS

The present disclosure will be more fully understood from the detailed description and accompanying drawings provided below, which are provided solely for explanation purposes and do not limit the scope of the present disclosure.

FIG. 1 illustrates an example of a cross-sectional structure of a semiconductor device according to embodiments of the present disclosure.

FIG. 2 to FIG. 5 schematically illustrate polarization behaviors of semiconductor devices according to embodiments of the present disclosure.

FIG. 6 illustrates an example of a planar structure of a semiconductor device according to embodiments of the present disclosure.

FIG. 7 illustrates an example of a cross-sectional structure taken along the I–I’ and II–II’ sections of FIG. 6.

FIG. 8 is an enlarged view of a region 10 of FIG. 7.

FIG. 9 to FIG. 15 illustrate examples of a method for manufacturing a semiconductor device according to embodiments of the present disclosure.

### DETAILED DESCRIPTION

Hereinafter, embodiments of the disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, such details may be omitted. As used herein, terms such as “comprises,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Such denotations as “first," "second," "A," "B," "(a)," and "(b)" may be used to describe components of the disclosure. These denotations are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Here, the intervening component may be included in one or more of the two or more components that are “connected,” “coupled,” or “linked” to each other.

When terms such as “after,” “next to,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the disclosure are described in detail with reference to the accompanying drawings.

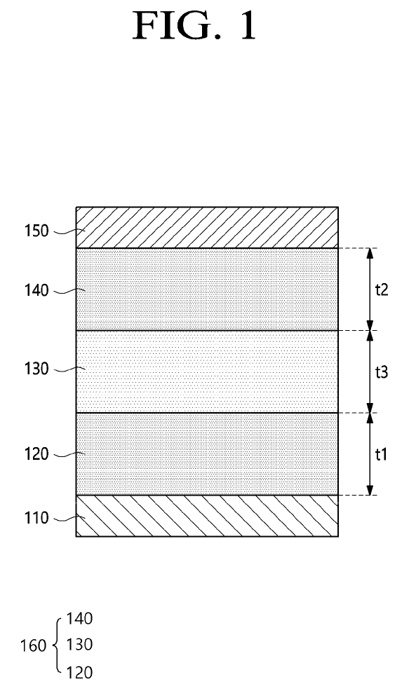

FIG. 1 illustrates an example of a cross-sectional structure of a semiconductor device according to embodiments of the present disclosure.

Referring to FIG. 1, a semiconductor device according to embodiments of the present disclosure includes a first electrode 110, a first ferroelectric layer 120, a domain separation layer 130, a second ferroelectric layer 140, and a second electrode 150. The semiconductor device may further include additional components beyond the above-described ones, and is not necessarily limited to only the illustrated configuration.

The first electrode 110 and the second electrode 150 are disposed apart from each other. A dielectric layer 160 is disposed between the first electrode 110 and the second electrode 150. The dielectric layer 160 includes the first ferroelectric layer 120, the domain separation layer 130, and the second ferroelectric layer 140. The domain separation layer 130 is disposed between the first ferroelectric layer 120 and the second ferroelectric layer 140.

The first electrode 110 may include a conductive material such as a metal, a metal nitride, a metal silicide, polysilicon, conductive carbon, or a combination thereof. For example, the first electrode 110 may include titanium nitride.

The first ferroelectric layer 120 may be disposed on the first electrode 110. The first ferroelectric layer 120 may include a ferroelectric material (for example a material having ferroelectric properties or ferroelectricity). For example, the first ferroelectric layer 120 may include hafnium oxide, hafnium zirconium oxide, or a combination thereof.

In one embodiment, the first ferroelectric layer 120 may further include a dopant. In one embodiment, the dopants doped into the first ferroelectric layer 120 may serve to stabilize the crystal structure of the first ferroelectric layer 120 and reduce the ferroelectricity of the first ferroelectric layer 120. For example, the dopants doped into the first ferroelectric layer 120 may include aluminum (Al), yttrium (Y), silicon (Si), lanthanum (La), or a combination thereof. In one embodiment, the doping concentration of the dopant in the first ferroelectric layer 120 may range from 0% to 20%.

In one embodiment, when the first ferroelectric layer 120 includes a dopant (e.g., yttrium, aluminum, silicon, etc.) having a higher bandgap than that of the first ferroelectric layer 120 itself, the through-current flowing through the dielectric layer 160 may be minimized.

In one embodiment, the first ferroelectric layer 120 may have a crystal structure of a tetragonal crystal system or an orthorhombic crystal system.

The domain separation layer 130 may be disposed on the first ferroelectric layer 120. In one embodiment, the domain separation layer 130 may serve to separate the domains of the first ferroelectric layer 120 and the second ferroelectric layer 140. A domain may refer to a region within the first ferroelectric layer 120 or the second ferroelectric layer 140 in which the direction of spontaneous electric polarization is uniform. Due to the domain separation layer 130, the domains included in the first ferroelectric layer 120 may differ from those in the second ferroelectric layer 140. In other words, the direction of spontaneous electric polarization of the domains in the first ferroelectric layer 120 may be different from that of the domains in the second ferroelectric layer 140. In other words, the domains in the first ferroelectric layer 120 may be decoupled from those in the second ferroelectric layer 140.

The domain separation layer 130 may include a material having a crystal structure similar to that of the first ferroelectric layer 120 and the second ferroelectric layer 140. In one embodiment, the domain separation layer 130 may include an oxide having a fluorite structure. For example, the domain separation layer 130 may include zirconium oxide, cerium oxide, or a combination thereof. In one embodiment, the domain separation layer 130 may have a crystal structure of a tetragonal crystal system or a cubic crystal system.

In one embodiment, the domain separation layer 130 may further include a dopant. A dopant doped into the domain separation layer 130 may serve to stabilize the crystal structure of the domain separation layer 130.

The dopant doped into the domain separation layer 130 may include metal cations having a valency different from that of the metal element included in the domain separation layer 130. In one embodiment, the dopant doped into the domain separation layer 130 may include metal cations having a lower valency than that of the metal element in the domain separation layer 130. For example, when the domain separation layer 130 includes zirconium oxide, the dopant doped into the domain separation layer 130 may include metal cations having a valency lower than that of zirconium (which is 4), such as aluminum (Al), yttrium (Y), lanthanum (La), or a combination thereof. In another embodiment, the dopant doped into the domain separation layer 130 may include metal cations having a higher valency than that of the metal element in the domain separation layer 130. For instance, if the domain separation layer 130 includes zirconium oxide, the dopant doped into the domain separation layer 130 may include niobium (Nb), tantalum (Ta), or a combination thereof. In one embodiment, the doping concentration of the dopant doped into the domain separation layer 130 may range from 0% to 20%.

In one embodiment, the domain separation layer 130 may have non-ferroelectricity (i.e., may be non-ferroelectric). For example, the domain separation layer 130 may have paraelectricity (i.e., may be a paraelectric material).

The greater the thickness of the domain separation layer 130, the more effectively (for example, greater decoupling) the domains of the first ferroelectric layer 120 and the second ferroelectric layer 140 may be separated. Additionally, the lower the dielectric constant of the material included in the domain separation layer 130, the more effectively the domains of the first ferroelectric layer 120 and the second ferroelectric layer 140 may be separated.

In one embodiment, the thickness t3 of the domain separation layer 130 may be 5% to 50% of the thickness of the dielectric layer 160. In another embodiment, the thickness t3 may be 20% to 33% of the thickness of the dielectric layer 160. For example, if the thickness of the dielectric layer 160 is 50 angstroms, the thickness t3 of the domain separation layer 130 may range from 10 angstroms to 17 angstroms. If the thickness t3 of the domain separation layer 130 is too small, the distance between the first ferroelectric layer 120 and the second ferroelectric layer 140 may be too short (for decoupling), and thus the domains in the first ferroelectric layer 120 may not be separated from the domains in the second ferroelectric layer 140. Accordingly, the thickness t3 of the domain separation layer 130 should be at least 10 angstroms (or at least 20% of the thickness of the dielectric layer 160). On the other hand, if the thickness t3 of the domain separation layer 130 is too large, the domain separation layer 130 may have a relatively lower dielectric constant compared to the first and second ferroelectric layers, and thus the dielectric constant of the dielectric layer 160 may become too low. Accordingly, the thickness t3 of the domain separation layer 130 should be no greater than 17 angstroms (or no greater than 33% of the thickness of the dielectric layer 160).

The second ferroelectric layer 140 may be disposed on the domain separation layer 130. The second ferroelectric layer 140 may include a material having ferroelectricity. For example, the second ferroelectric layer 140 may include hafnium oxide, hafnium zirconium oxide, or a combination thereof. In one embodiment, the second ferroelectric layer 140 may include the same material as the first ferroelectric layer 120.

In one embodiment, the second ferroelectric layer 140 may further include a dopant. In one embodiment, the dopant doped into the second ferroelectric layer 140 may serve to stabilize the crystal structure of the second ferroelectric layer 140 and weaken its ferroelectricity. For example, the dopant doped into the second ferroelectric layer 140 may include aluminum (Al), yttrium (Y), silicon (Si), lanthanum (La), or a combination thereof. In one embodiment, the doping concentration of the dopant doped into the second ferroelectric layer 140 may range from 0% to 20%.

In one embodiment, if the second ferroelectric layer 140 includes a dopant having a higher bandgap than the second ferroelectric layer 140 itself (for example, yttrium, aluminum, silicon, etc.), the leakage current flowing through the dielectric layer 160 may be minimized.

In one embodiment, the second ferroelectric layer 140 may have a crystal structure of a tetragonal crystal system or an orthorhombic crystal system.

As described above, domains included in the second ferroelectric layer 140 may be different from the domains included in the first ferroelectric layer 120. In other words, the direction of spontaneous electric polarization in the second ferroelectric layer 140 may differ from that of the first ferroelectric layer 120. Accordingly, a voltage required to reverse the polarization direction of the second ferroelectric layer 140 may differ from a voltage required to reverse the polarization direction of the first ferroelectric layer 120.

In one embodiment, the thickness t2 of the second ferroelectric layer 140 may be substantially the same as the thickness t1 of the first ferroelectric layer 120. However, this is not limited thereto, and in some cases, the thickness t1 of the first ferroelectric layer 120 and the thickness t2 of the second ferroelectric layer 140 may differ.

In one embodiment, the thickness ratio of the first ferroelectric layer 120, the domain separation layer 130, and the second ferroelectric layer 140 may be approximately 1:1:1. In one embodiment, the sum of the thicknesses t1 of the first ferroelectric layer 120, t2 of the second ferroelectric layer 140, and t3 of the domain separation layer 130 may range from 30 angstroms to 50 angstroms.

The second electrode 150 is disposed on the second ferroelectric layer 140. The second electrode 150 may include a conductive material such as metal, metal nitride, metal silicide, polysilicon, conductive carbon, or a combination thereof. For example, the second electrode 150 may include titanium nitride.

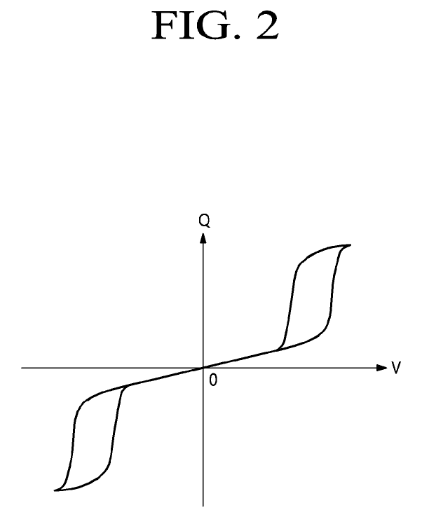

FIG. 2 to FIG. 5 are diagrams schematically illustrating the polarization behavior of the semiconductor device according to embodiments of the present disclosure.

FIG. 2 is a diagram schematically illustrating a change in charge Q due to polarization within the semiconductor device when a voltage V is applied from outside the semiconductor device.

Referring to FIG. 2, when a voltage is applied externally to the semiconductor device, polarization may be formed in a specific direction inside the semiconductor device. In one embodiment, polarization resulting from the external voltage may be formed in the first ferroelectric layer 120 and the second ferroelectric layer 140. When the external voltage is zero, the amount of charge due to polarization in the semiconductor device may also be zero. When the external voltage has a positive value, the charge due to polarization in the semiconductor device may be positive. Conversely, when the external voltage has a negative value, the charge due to polarization in the semiconductor device may be negative. The semiconductor device according to embodiments of the present disclosure may exhibit antiferroelectricity (or, in some instances, antiferroelectric properties, comprise an antiferroelectric material).

However, as the external voltage increases or decreases from zero, the semiconductor device may exhibit polarization behavior similar to that of a ferroelectric material. For example, when the magnitude of the externally applied voltage exceeds a certain threshold, the polarization direction of the first ferroelectric layer 120 or the second ferroelectric layer 140 may be reversed. For example, a positive voltage may be applied to the second electrode 150 of FIG. 1 and a ground voltage may be applied to the first electrode 110. In this case, the polarization direction of the second ferroelectric layer 140 may be reversed from a direction from the second electrode 150 toward the first electrode 110 to a direction from the first electrode 110 toward the second electrode 150. Alternatively, a negative voltage is applied to the second electrode 150 of FIG. 1 and a ground voltage is applied to the first electrode 110. In this case, the polarization direction of the first ferroelectric layer 120 may be reversed from a direction from the first electrode 110 toward the second electrode 150 to a direction from the second electrode 150 toward the first electrode 110. In one embodiment, the first ferroelectric layer 120 and the second ferroelectric layer 140 may exhibit ferroelectricity, while the dielectric layer 160 including the first ferroelectric layer 120, the domain separation layer 130, and the second ferroelectric layer 140 may exhibit antiferroelectricity (for example, be antiferroelectric or exhibit antiferroelectric behavior).

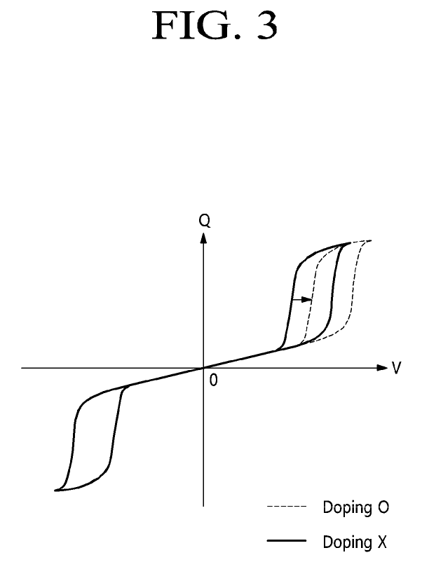

FIG. 3 is a diagram schematically illustrating a change in charge Q due to polarization in the semiconductor device when a voltage V is applied externally, in a case where a dopant is doped into the second ferroelectric layer 140.

Referring to FIG. 3, by selectively doping only the second ferroelectric layer 140 with a dopant, the polarization behavior of the second ferroelectric layer 140 may be selectively changed alone (for example, by itself, separate from other components of the semiconductor device including the first ferroelectric layer 120).

In one embodiment, the first ferroelectric layer 120 may not include any dopant, while the second ferroelectric layer 140 may include a dopant. The dopant included in the second ferroelectric layer 140 may include aluminum (Al), yttrium (Y), silicon (Si), lanthanum (La), or a combination thereof.

Referring to FIG. 2 and FIG. 3, when the second ferroelectric layer 140 includes the above-described dopant, the crystal structure of the second ferroelectric layer 140 may be stabilized. As a result, a higher positive voltage (for example, a positive voltage on the second electrode 150 and a ground voltage on the first electrode 110) may be required to reverse the polarization direction of the second ferroelectric layer 140. In other words, the ferroelectricity of the second ferroelectric layer 140 may be weakened.

Since only the second ferroelectric layer 140 includes the dopant, the external voltage required to reverse the polarization direction of the first ferroelectric layer 120 may be the same as the external voltage required to reverse the polarization direction of the first ferroelectric layer 120 as shown in FIG. 2. That is, since the first ferroelectric layer 120 includes a domain different from that of the second ferroelectric layer 140, the polarization behavior of the first ferroelectric layer 120 may not be affected by that of the second ferroelectric layer 140.

Although FIG. 3 only describes the case where a dopant is doped into the second ferroelectric layer 140, the polarization behavior of the semiconductor device may also change when the thickness of the second ferroelectric layer 140 is varied.

For example, when the thickness of the second ferroelectric layer 140 increases, the size of the domains contained in the second ferroelectric layer 140 may increase. As the domain size contained in the second ferroelectric layer 140 increases, the energy required to reverse the polarization direction decreases. Accordingly, the magnitude of the external voltage required to reverse the polarization direction of the second ferroelectric layer 140 may be reduced. As a result, the ferroelectricity of the second ferroelectric layer 140 may be enhanced.

Conversely, when the thickness of the second ferroelectric layer 140 decreases, the domain size within the second ferroelectric layer 140 may decrease, and the energy required to reverse the polarization direction increases, thereby increasing the external voltage required to reverse the polarization direction of the second ferroelectric layer 140. Accordingly, the ferroelectricity of the second ferroelectric layer 140 may be weakened.

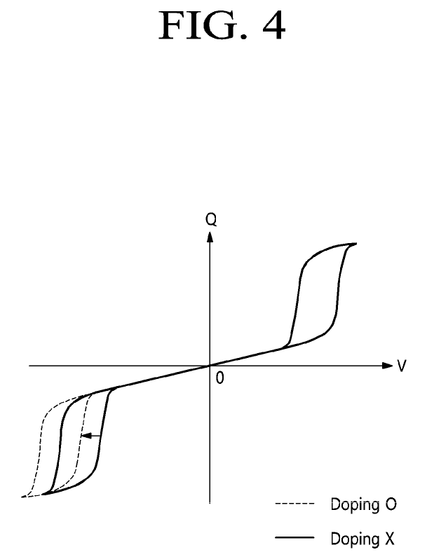

FIG. 4 is a diagram schematically illustrating a change in charge Q due to polarization in the semiconductor device when a voltage V is applied externally, in a case where a dopant is doped into the first ferroelectric layer 120.

In one embodiment, by selectively doping only the first ferroelectric layer 120 with a dopant, the polarization behavior of the first ferroelectric layer 120 may be selectively changed alone (for example, separate from other components of the semiconductor device including the second ferroelectric layer 140).

In one embodiment, the second ferroelectric layer 140 may not include any dopant, while the first ferroelectric layer 120 may include a dopant. The dopant included in the first ferroelectric layer 120 may include aluminum (Al), yttrium (Y), silicon (Si), lanthanum (La), or a combination thereof.

Referring to FIG. 2 and FIG. 4, when the first ferroelectric layer 120 includes the above-described dopant, the crystal structure of the first ferroelectric layer 120 may be stabilized. As a result, a larger negative voltage (e.g., a negative voltage applied to the second electrode 150 and a ground voltage applied to the first electrode 110) may be required to reverse the polarization direction of the first ferroelectric layer 120. In other words, the ferroelectricity of the first ferroelectric layer 120 may be weakened.

Since only the first ferroelectric layer 120 includes a dopant, the external voltage required to reverse the polarization direction of the second ferroelectric layer 140 may be the same as the voltage required to reverse the polarization direction of the second ferroelectric layer 140, as shown in FIG. 2. Because the second ferroelectric layer 140 includes a domain different from that of the first ferroelectric layer 120, the polarization behavior of the second ferroelectric layer 140 may not be affected by that of the first ferroelectric layer 120.

Although FIG. 4 only describes the case where a dopant is doped into the first ferroelectric layer 120, the polarization behavior of the semiconductor device may also change when the thickness of the first ferroelectric layer 120 is varied.

As previously described with reference to FIG. 3, when the thickness of the first ferroelectric layer 120 increases, the ferroelectricity of the first ferroelectric layer 120 may be enhanced. Conversely, when the thickness of the first ferroelectric layer 120 decreases, the ferroelectricity of the first ferroelectric layer 120 may be weakened.

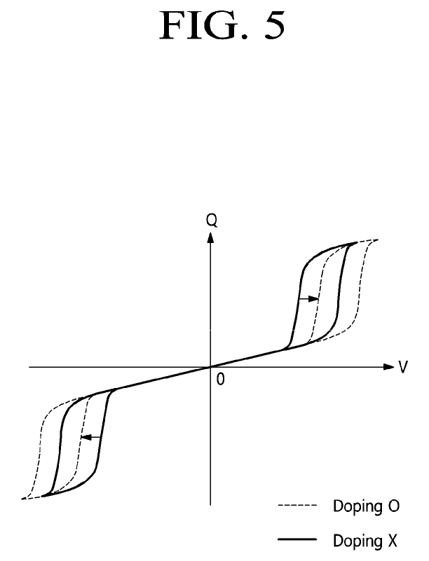

FIG. 5 is a diagram schematically illustrating a change in charge Q due to polarization in the semiconductor device when a voltage V is applied externally, in a case where the dopants are doped into both the first ferroelectric layer 120 and the second ferroelectric layer 140.

In one embodiment, both the first ferroelectric layer 120 and the second ferroelectric layer 140 may include a dopant. The dopants included in the first ferroelectric layer 120 and the second ferroelectric layer 140 may include aluminum (Al), yttrium (Y), silicon (Si), lanthanum (La), or a combination thereof.

Referring to FIG. 2 and FIG. 5, when the first ferroelectric layer 120 includes the above-described dopant, a larger negative voltage (e.g., a negative voltage applied to the second electrode 150 and a ground voltage applied to the first electrode 110) may be required to reverse the polarization direction of the first ferroelectric layer 120. In other words, the ferroelectricity of the first ferroelectric layer 120 may be weakened.

Similarly, when the second ferroelectric layer 140 includes the above-described dopant, a larger negative voltage (e.g., a negative voltage applied to the second electrode 150 and a ground voltage applied to the first electrode 110) may be required to reverse the polarization direction of the second ferroelectric layer 140. In other words, the ferroelectricity of the second ferroelectric layer 140 may be weakened.

Although FIG. 5 only describes the case where both the first ferroelectric layer 120 and the second ferroelectric layer 140 include dopants, as described above, the polarization behavior of the semiconductor device may also vary depending on the thickness of the first and second ferroelectric layers 120 and 140.

Referring again to FIG. 1 through FIG. 5, the semiconductor device according to embodiments of the present disclosure may include the domain separation layer 130 disposed between the first ferroelectric layer 120 and the second ferroelectric layer 140. The domain separation layer 130 may comprise a dopant which may include a metal cation having a valency different from that of a metal element included in the domain separation layer 130.

As the semiconductor device includes the domain separation layer 130 and the domain separation layer 130 includes a metal cation as a dopant having a valency different from that of a metal element contained therein, domains of the first ferroelectric layer 120 and the second ferroelectric layer 140 may be effectively separated. That is, the polarization behaviors of the first ferroelectric layer 120 and the second ferroelectric layer 140 may be decoupled.

Since the polarization behaviors of the first ferroelectric layer 120 and the second ferroelectric layer 140 may be decoupled, when a dopant is doped into either the first ferroelectric layer 120 or the second ferroelectric layer 140, the polarization behavior of each layer may be individually controlled.

In particular, when the domain separation layer 130 is disposed within the dielectric layer of a capacitor of a dynamic random access memory (DRAM), degradation of device characteristics due to repeated switching operations may be prevented. This can be described in more detail as follows. The domain separation layer 130 disposed within the dielectric layer of the capacitor may separate the domains of the dielectric layer. The polarization behaviors of the dielectric layers separated by the domain separation layer may be decoupled from one another. In this case, if dopants are doped into each of the dielectric layers separated by the domain separation layer 130, the absolute value of the voltage required to reverse the polarization of each dielectric layer increases, thereby weakening the ferroelectricity of each layer. Accordingly, even when an abnormally high voltage is applied to the DRAM or repeated switching operations are performed, polarization reversal may not occur, thus preventing degradation of device characteristics.

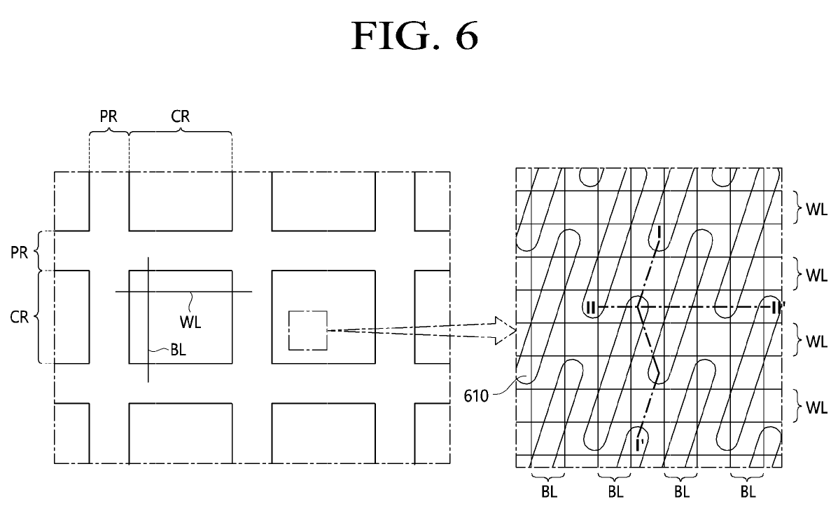

FIG. 6 is a diagram illustrating an example of a planar structure of a semiconductor device according to embodiments of the present disclosure.

The semiconductor device shown in FIG. 6 is an illustrative example corresponding to the semiconductor device described with reference to FIG. 1 and should not be construed as limiting the scope of the present disclosure.

Referring to FIG. 6, the semiconductor device includes a cell region CR and a peripheral region PR. The cell region CR is a region where memory cells are disposed. The peripheral region PR is a region where peripheral circuits for supplying various voltages or signals to the memory cells disposed in the cell region CR are arranged. The peripheral region PR is disposed around the cell region CR. In one embodiment, the peripheral region PR may surround the cell region CR.

The semiconductor device may include bit lines BL, word lines WL, and active regions 610. The active regions 610 are spaced apart from each other. The bit lines BL and word lines WL are disposed to cross the active regions 610. In one embodiment, a bit line BL may cross a single active region 610. In another embodiment, two word lines WL may cross a single active region 610. The bit lines BL and word lines WL may be disposed to overlap the cell region CR and may extend into the peripheral region PR.

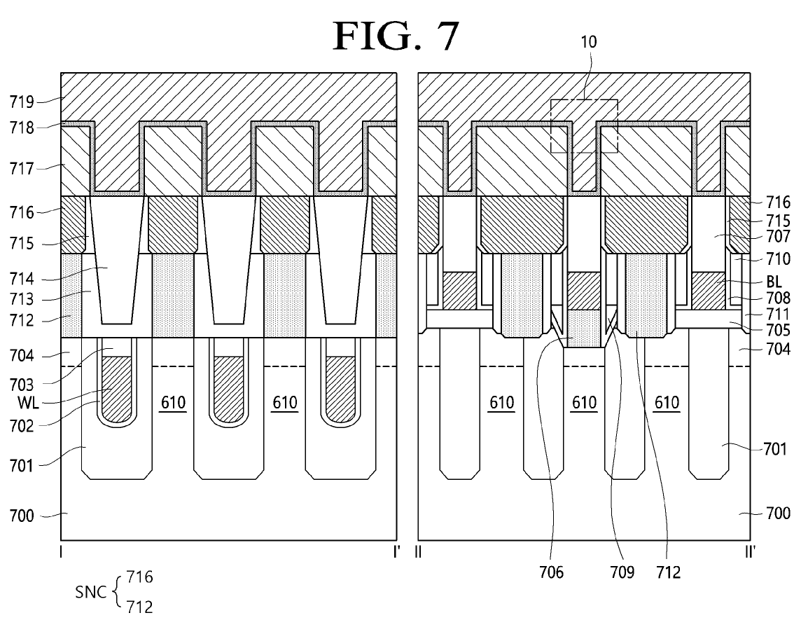

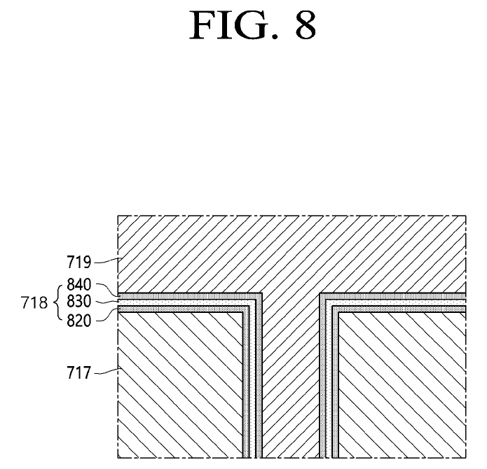

FIG. 7 is a diagram illustrating a cross-sectional structure taken along line I-I′ and II-II′ in FIG. 6. FIG. 8 is a magnified view of region 10 of FIG. 7.

Referring to FIG. 7 and FIG. 8, the semiconductor device may include a substrate 700, an active region 610, a device isolation layer 701, a gate insulating layer 702, a word line WL, a gate capping layer 703, a source/drain region 704, an interlayer insulating layer 705, a bit line contact 706, a bit line BL, a bit line capping layer 707, a first spacer 708, a gap-fill spacer 709, a second spacer 710, a third spacer 711, a lower contact plug 712, a first insulating layer 713, a second insulating layer 714, an upper spacer 715, an upper contact plug 716, a lower electrode 717, a dielectric layer 718, and an upper electrode 719.

The lower contact plug 712 and the upper contact plug 716 constitute a lower electrode contact plug (SNC).

The substrate 700 may include a semiconductor substrate such as a silicon wafer or a Silicon On Insulator (SOI) wafer. The substrate 700 may include a group III-V compound semiconductor substrate, such as GaAs. The substrate 700 may include single-crystal silicon, polysilicon, amorphous silicon, single-crystal silicon germanium, polycrystalline silicon germanium, carbon-doped silicon, or a combination thereof.

The device isolation layer 701 defining the active region 610 is disposed within the substrate 700. The device isolation layer 701 may be formed using trench isolation technology such as Shallow Trench Isolation (STI). The device isolation layer 701 may include silicon oxide, silicon nitride, silicon oxynitride, low-k dielectric, high-k dielectric, or a combination thereof.

The gate insulating layer 702 is disposed within the device isolation layer 701. The word line WL is disposed on an inner surface of the gate insulating layer 702. The gate capping layer 703 is disposed on the word line WL. The gate insulating layer 702 may be arranged to surround the side surfaces and the bottom surface of the word line WL. The top surface of the word line WL may be located lower than the top surface of the active region 610. The source/drain region 704 may be disposed in the active region 610 adjacent to the word line WL.

The gate insulating layer 702 may include silicon oxide, silicon nitride, silicon oxynitride, high-k dielectric, or a combination thereof. The word line WL may include a conductive material such as metal, metal oxide, metal nitride, metal silicide, polysilicon, conductive carbon, or a combination thereof. The gate capping layer 703 may include silicon oxide, silicon nitride, silicon oxynitride, low-k dielectric, high-k dielectric, or a combination thereof.

The interlayer insulating layer 705 may be disposed on the device isolation layer 701, the gate capping layer 703, and the source/drain region 704. The bit line contact 706 may contact (or be in contact with) the source/drain region 704 by passing through the interlayer insulating layer 705. Each active region 610 may be electrically connected to at least one bit line contact 706 through a corresponding one of the source/drain regions 704. The interlayer insulating layer 705 may include silicon oxide, silicon nitride, silicon oxynitride, low-k dielectric, high-k dielectric, or a combination thereof.

The bit line BL is disposed on the interlayer insulating layer 705. The bit line BL may be in contact with at least one bit line contact 706. The bit line capping layer 707 may cover the bit line BL. The bit line BL and the bit line contact 706 may include a conductive material such as metal, metal oxide, metal nitride, metal silicide, polysilicon, conductive carbon, or a combination thereof. The bit line capping layer 707 may include a dielectric such as silicon oxide, silicon nitride, silicon oxynitride, low-k dielectric, high-k dielectric, or a combination thereof.

The first spacer 708 may be disposed on the side surfaces of the bit line BL and the bit line capping layer 707 and may extend over the side surfaces of the bit line contact 706 and the interlayer insulating layer 705. The gap-fill spacer 709 may be disposed on the first spacer 708 adjacent to the side surfaces of the bit line contact 706. The first spacer 708 may extend between the gap-fill spacer 709 and the device isolation layer 701.

The second spacer 710 may be disposed on the first spacer 708. The side surfaces of the second spacer 710 may be in contact with the side surfaces of the first spacer 708. The bottom surface of the second spacer 710 may be in contact with the first spacer 708.

The third spacer 711 may be disposed on the second spacer 710. The side surfaces of the third spacer 711 may be in contact with the side surfaces of the second spacer 710. The third spacer 711 may extend into the source/drain region 704 through the interlayer insulating layer 705. The side surfaces of the third spacer 711 may be in contact with the first spacer 708 and the interlayer insulating layer 705. The bottom end of the third spacer 711 may be located lower than the top end of the source/drain region 704.

The first spacer 708, the second spacer 710, and the third spacer 711 may include a dielectric such as silicon oxide, silicon nitride, silicon oxynitride, low-k dielectric, high-k dielectric, or a combination thereof.

Each lower contact plug 712 may be in contact with a corresponding one of the source/drain regions 704 in the active region 610. The upper contact plug 716 may be in contact with the lower contact plug 712. At least a portion of the lower contact plug 712 may overlap an upper part of a corresponding one of the active regions 610. The horizontal width of the upper contact plug 716 may be greater than that of the lower contact plug 712.

The lower contact plug 712 and the upper contact plug 716 may include a conductive material such as metal, metal oxide, metal nitride, metal silicide, polysilicon, conductive carbon, or a combination thereof.

The bottom end of the lower contact plug 712 may be located at a height lower than the top end of the source/drain region 704. The bottom end of the lower contact plug 712 may be located lower than the bottom end of the third spacer 711. The top end of the lower contact plug 712 may be located higher than the top surfaces of adjacent bit lines BL.

The second insulating layer 714 may be disposed between lower electrode contact plugs (SNC). The first insulating layer 713 may surround the side surfaces and the bottom surface of the second insulating layer 714. The top end of the first insulating layer 713 may be located lower than the top surfaces of the second insulating layer 714. The upper spacer 715 may be disposed on the first insulating layer 713 and may surround the side surfaces of the second insulating layer 714. The upper spacer 715 may be disposed between the second insulating layer 714 and the upper contact plug 716. The upper spacer 715 may extend between the bit line capping layer 707 and the upper contact plug 716.

The second insulating layer 714 may include silicon oxide, silicon nitride, silicon oxynitride, low-k dielectric, high-k dielectric, or a combination thereof.

The lower electrode 717 may be disposed on the lower electrode contact plug (SNC). In one embodiment, the lower electrode 717 may be referred to as a storage node. The storage node may be connected to the lower electrode contact plug (SNC). The storage node may have a pillar shape, a cylindrical shape, a box shape, or a combination thereof.

The dielectric layer 718 may be disposed on the lower electrode 717. The dielectric layer 718 may cover the side and top surfaces of the lower electrode 717 and the top surface of the second insulating layer 714. Referring to FIG. 8, the dielectric layer 718 may include a first ferroelectric layer 820, a domain separation layer 830 on the first ferroelectric layer 820, and a second ferroelectric layer 840 on the domain separation layer 830. The first ferroelectric layer 820, the domain separation layer 830, and the second ferroelectric layer 840 may correspond to the first ferroelectric layer 120, the domain separation layer 130, and the second ferroelectric layer 140, respectively, as described with reference to FIG. 1.

The first ferroelectric layer 820 may include, for example, hafnium oxide, hafnium zirconium oxide, or a combination thereof.

In one embodiment, the first ferroelectric layer 820 may further include a dopant. In one embodiment, the dopants doped into the first ferroelectric layer 820 may stabilize the crystal structure of the first ferroelectric layer 820 and serve to weaken its ferroelectricity. For example, the dopants doped into the first ferroelectric layer 820 may include aluminum (Al), yttrium (Y), silicon (Si), lanthanum (La), or a combination thereof. In one embodiment, the doping concentration of the dopant doped into the first ferroelectric layer 820 may range from 0% to 20%.

In one embodiment, the domain separation layer 830 may serve to separate the domains of the first ferroelectric layer 820 and the second ferroelectric layer 840. Due to the domain separation layer 830, the domains included in the first ferroelectric layer 820 may be different from those included in the second ferroelectric layer 840. In other words, the direction of spontaneous electric polarization of the domains in the first ferroelectric layer 820 may be different from that of the domains in the second ferroelectric layer 840. That is, the domains included in the first ferroelectric layer 820 may be decoupled from the domains included in the second ferroelectric layer 840.

The domain separation layer 830 may include a material having a crystal structure similar to that of the first ferroelectric layer 820 and the second ferroelectric layer 840. In one embodiment, the domain separation layer 830 may include an oxide having a fluorite structure. For example, the domain separation layer 830 may include zirconium oxide, cerium oxide, or a combination thereof. In one embodiment, the domain separation layer 830 may have a crystal structure of a tetragonal crystal system or a cubic crystal system.

In one embodiment, the domain separation layer 830 may further include a dopant. In one embodiment, the dopant doped into the domain separation layer 830 may serve to stabilize the crystal structure of the domain separation layer 830.

The dopant doped into the domain separation layer 830 may include a metal cation having a valency different from that of a metal element included in the domain separation layer 830. In one embodiment, the dopant doped into the domain separation layer 830 may include a metal cation having a lower valency than that of the metal element included in the domain separation layer 830. For example, when the domain separation layer 830 includes zirconium oxide, the dopant doped into the domain separation layer 830 may include a metal cation having a valency lower than that of zirconium (which is 4), such as aluminum (Al), yttrium (Y), lanthanum (La), or a combination thereof. In another embodiment, the dopant may include a metal cation having a higher valency than that of the metal element included in the domain separation layer 830. For example, when the domain separation layer 830 includes zirconium oxide, the dopant doped into the domain separation layer 830 may include niobium (Nb), tantalum (Ta), or a combination thereof. In one embodiment, the doping concentration of the dopant doped into the domain separation layer 830 may range from 0% to 20%.

In one embodiment, the domain separation layer 830 may exhibit non-ferroelectricity. For example, the domain separation layer 830 may exhibit paraelectricity.

As the thickness of the domain separation layer 830 increases, the domains of the first ferroelectric layer 820 and the second ferroelectric layer 840 may be better separated. Additionally, as the dielectric constant of the material included in the domain separation layer 830 decreases, the domains of the first ferroelectric layer 820 and the second ferroelectric layer 840 may be more effectively separated.

In one embodiment, the thickness of the domain separation layer 830 may range from 5% to 50% of the thickness of the dielectric layer 718. In another embodiment, the thickness of the domain separation layer 830 may range from 20% to 33% of the thickness of the dielectric layer 718. For example, when the thickness of the dielectric layer 718 is 50 angstroms, the thickness of the domain separation layer 830 may be 10 angstroms or more and 17 angstroms or less. If the thickness of the domain separation layer 830 is too small, the distance between the first ferroelectric layer 820 and the second ferroelectric layer 840 becomes small, which may result in the domains of the first ferroelectric layer 820 and the second ferroelectric layer 840 not being sufficiently separated. Accordingly, the thickness of the domain separation layer 830 should be at least 10 angstroms (or at least 20% of the thickness of the dielectric layer 718). In addition, if the thickness of the domain separation layer 830 is too large, the dielectric constant of the dielectric layer 718 may become too low, since the domain separation layer 830 has a relatively lower dielectric constant compared to the first ferroelectric layer 820 and the second ferroelectric layer 840). Accordingly, the thickness of the domain separation layer 830 should be no greater than 17 angstroms (or no greater than 33% of the thickness of the dielectric layer 718).

The second ferroelectric layer 840 may include a material having ferroelectricity. For example, the second ferroelectric layer 840 may include hafnium oxide, hafnium zirconium oxide, or a combination thereof. In one embodiment, the second ferroelectric layer 840 may include the same material as that of the first ferroelectric layer 820.

In one embodiment, the second ferroelectric layer 840 may further include a dopant. In one embodiment, the dopant doped into the second ferroelectric layer 840 may serve to stabilize the crystal structure of the second ferroelectric layer 840 and weaken its ferroelectricity. For example, the dopant doped into the second ferroelectric layer 840 may include aluminum (Al), yttrium (Y), silicon (Si), lanthanum (La), or a combination thereof. In one embodiment, the doping concentration of the dopant doped into the second ferroelectric layer 840 may range from 0% to 20%.

An upper electrode 719 may be disposed on the dielectric layer 718. The lower electrode 717, the dielectric layer 718, and the upper electrode 719 may constitute a capacitor.

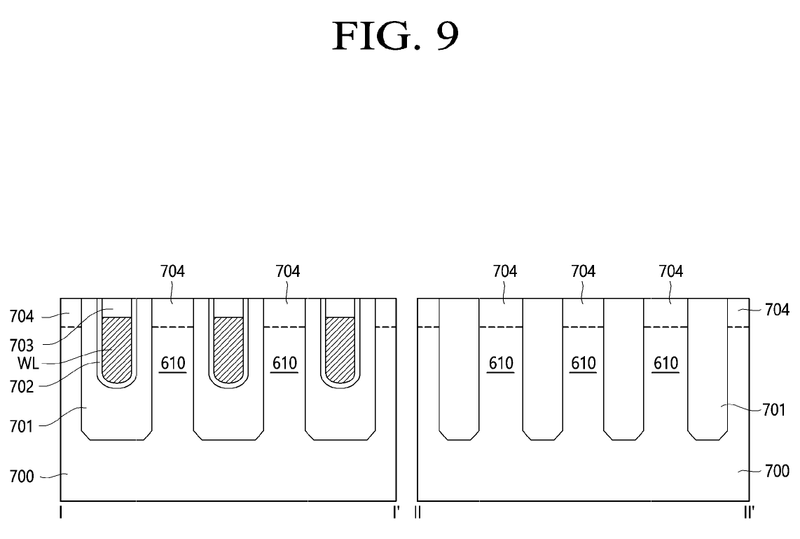

FIG. 9 through FIG. 15 are diagrams illustrating examples of a method for fabricating a semiconductor device according to embodiments of the present disclosure.

Referring to FIG. 9, an isolation layer 701 defining an active region 610 is formed in the substrate 700. A gate insulating layer 702, a word line WL, and a gate capping layer 703 are sequentially formed in the device isolation layer 701. The active region 610 may include single-crystal silicon having P-type impurities. The P-type impurities may include boron (B), boron monofluoride (BF), difluoro boron (BF₂), or a combination thereof.

A source/drain region 704 is formed in the active region 610 between the isolation layers 701. The source/drain region 704 may include single-crystal silicon having N-type impurities. The N-type impurities may include P, As, or a combination thereof.

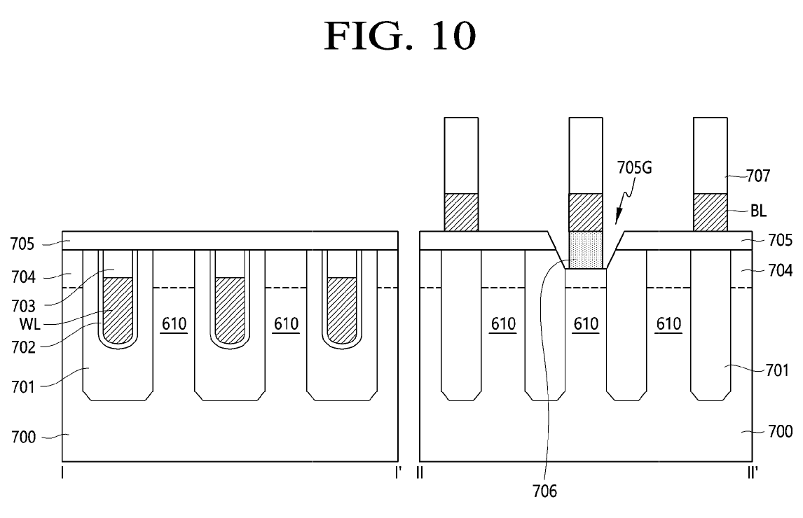

Referring to FIG. 10, an interlayer insulating layer 705 is formed to cover the device isolation layer 701, the gate insulating layer 702, the gate capping layer 703, and the source/drain region 704. A first contact hole 705G is formed to penetrate the interlayer insulating layer 705 and expose a corresponding one of the source/drain regions 704. A bit line contact 706 is formed in the first contact hole 705G. The bit line contact 706 is connected to the corresponding source/drain region 704. The bit line BL and the bit line capping layer 707 are sequentially formed on the bit line contact 706 and the interlayer insulating layer 705.

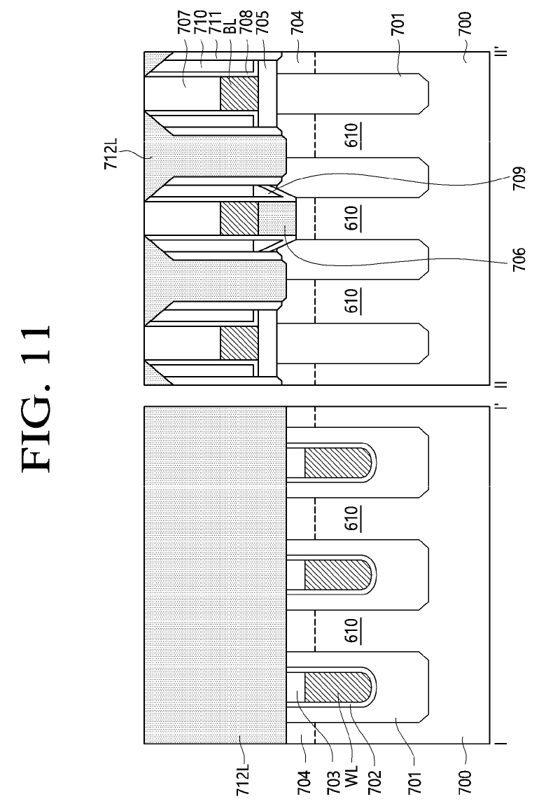

Referring to FIG. 11, a first spacer 708 is formed on the interlayer insulating layer 705, the bit line contact 706, the bit line BL, and the bit line capping layer 707. The gap-fill spacer 709 is formed in the region between the bit line contact 706 and the interlayer insulating layer 705, and between the bit line contact 706 and the device isolation layer 701. The process of forming the gap-fill spacer 709 may include an etch-back process.

A second spacer 710 is formed on the first spacer 708. The second spacer 710 is formed on the side surfaces of the bit line BL and the bit line capping layer 707, and on the top surface of the gap-fill spacer 709. During the process of forming the second spacer 710, part of the interlayer insulating layer 705 may be removed, exposing the source/drain region 704 and the device isolation layer 701.

A third spacer 711 is formed on the side surfaces of the second spacer 710 and the interlayer insulating layer 705. The process of forming the third spacer 711 may include an anisotropic etching process. During this process, the top surfaces of the source/drain region 704 and the device isolation layer 701 may be etched and recessed downward.

A lower contact layer 712L is formed on the outer surfaces of the source/drain region 704, the device isolation layer 701, and the third spacer 711. The lower contact layer 712L may be connected to the source/drain region 704. In one embodiment, the lower contact layer 712L may include doped polysilicon.

The process of forming the lower contact layer 712L may include a planarization process. The planarization process for forming the lower contact layer 712L may include a Chemical Mechanical Polishing (CMP) process, an etch-back process, or a combination thereof. The top surfaces of the lower contact layer 712L and the bit line capping layer 707 may lie on substantially the same plane.

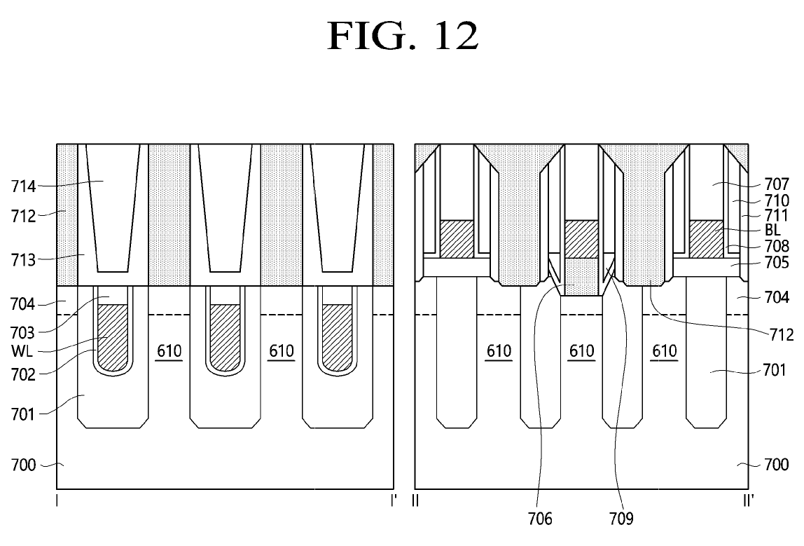

Referring to FIG. 11 and FIG. 12, a portion of the lower contact layer 712L overlapping with the device isolation layer 701 is at least partially removed, thereby forming the lower contact plug 712. A first insulating layer 713 is formed in the region between the lower contact plugs 712. The first insulating layer 713 may cover the side surfaces of the lower contact plugs 712 and the top surface of the device isolation layer 701.

A second insulating layer 714 is formed on the first insulating layer 713. A planarization process is performed so that the top surfaces of the bit line capping layer 707, the lower contact plug 712, the first insulating layer 713, and the second insulating layer 714 are exposed on the same plane.

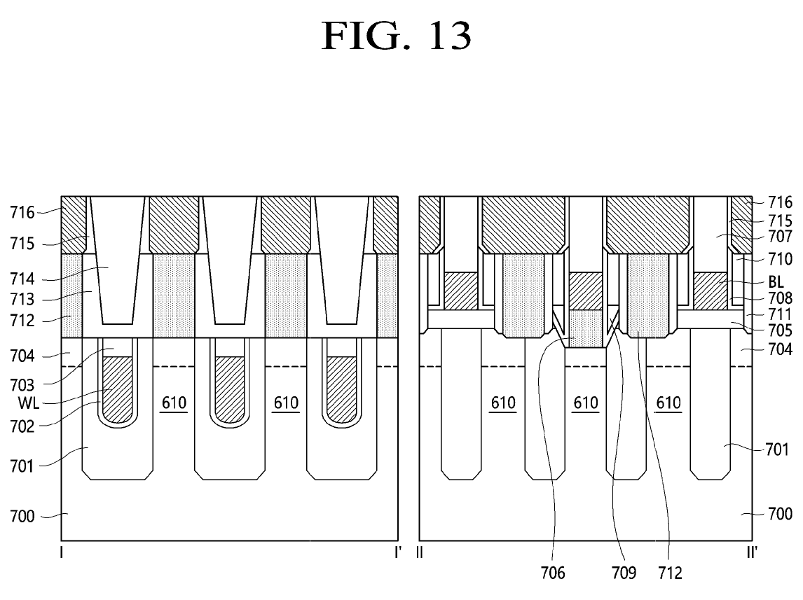

Referring to FIG. 13, at least a portion of the first spacer 708, the second spacer 710, the third spacer 711, the lower contact plug 712, and the first insulating layer 713 may be removed. As a result, the top surfaces of the first spacer 708, the second spacer 710, the third spacer 711, the lower contact plug 712, and the first insulating layer 713 may be recessed downward.

An upper spacer 715 and an upper contact plug 716 are formed in the region from which the first spacer 708, the second spacer 710, the third spacer 711, the lower contact plug 712, and the first insulating layer 713 have been removed. The upper spacer 715 may be in contact with the recessed top surface of the first insulating layer 713, the side surface of the second insulating layer 714, and the side surface of the bit line capping layer 707. The upper contact plug 716 may be connected to the corresponding lower contact plug 712. The upper contact plug 716 may be formed to be in contact with the top surface of the lower contact plug 712, the top surface of the third spacer 711, and the side surface of the upper spacer 715.

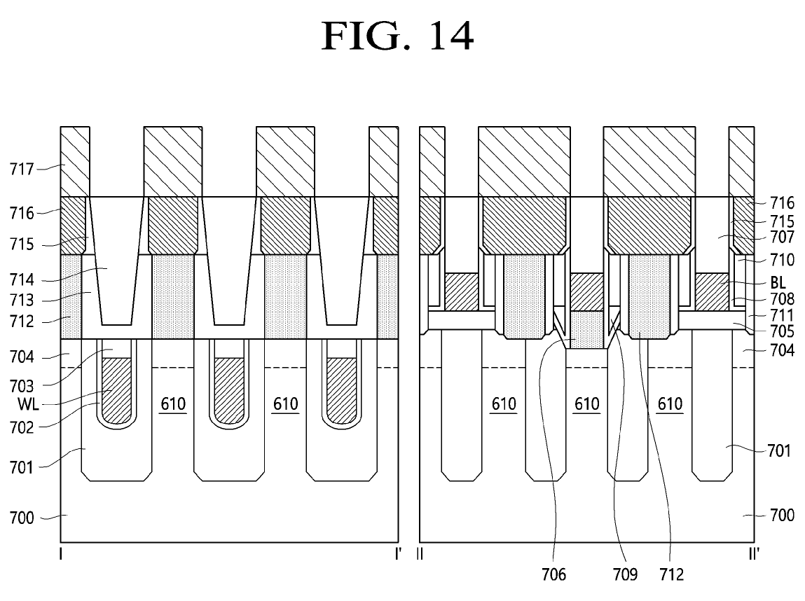

Referring to FIG. 14, the lower electrode 717 is formed on the upper contact plug 716. The lower electrode 717 may be formed on a corresponding upper contact plug 716. In one embodiment, the lower electrode 717 may include titanium nitride.

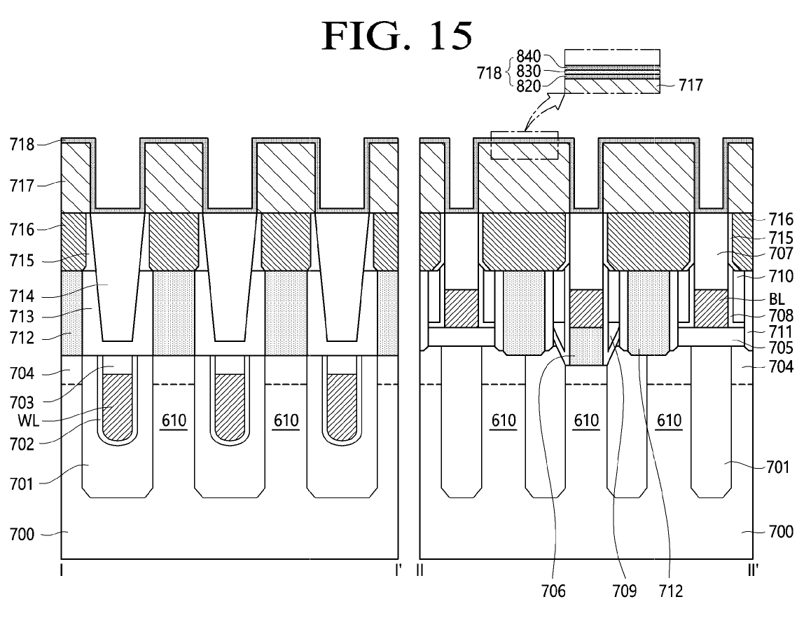

Referring to FIG. 15, the dielectric layer 718 (corresponding, for example, to the dielectric layer 160, described herein above) is formed on the side and top surfaces of the lower electrode 717 and on the top surface of the second insulating layer 714. The dielectric layer 718 includes a first ferroelectric layer 820, a domain separation layer 830, and a second ferroelectric layer 840. The first ferroelectric layer 820, the domain separation layer 830, and the second ferroelectric layer 840 are sequentially formed on the lower electrode 717. In one embodiment, the first ferroelectric layer 820, the domain separation layer 830, and the second ferroelectric layer 840 may be formed by an atomic layer deposition process, a pulsed layer deposition process, or a chemical vapor deposition process.

Referring again to FIG. 7, the upper electrode 719 is formed on the dielectric layer 718. The upper electrode 719 may cover the top and side surfaces of the dielectric layer 718.

The above description merely provides an illustrative explanation of the present disclosure. Accordingly, a person of ordinary skill in the art to which the present disclosure pertains can make various modifications and variations without departing from the essential characteristics of the present disclosure. In addition, the embodiments disclosed in the present disclosure are not intended to limit the scope of the present disclosure but rather to explain it. Accordingly, the scope of the present disclosure should not be limited by the embodiments.

What is claimed is:

1. A semiconductor device comprising:
a first electrode and a second electrode; and
a dielectric layer disposed between the first electrode and the second electrode,
wherein the dielectric layer comprises:
a first ferroelectric layer;
a second ferroelectric layer disposed between the first ferroelectric layer and the second electrode, the second ferroelectric layer having a domain different from a domain of the first ferroelectric layer; and
a domain separation layer disposed between the first ferroelectric layer and the second ferroelectric layer, the domain separation layer containing a first dopant and a metal element,
wherein the first dopant comprises a metal cation having a valency different from a valency of the metal element.

2. The semiconductor device according to claim 1,
wherein the domain separation layer comprises zirconium oxide, cerium oxide, or a combination thereof.

3. The semiconductor device according to claim 2,
wherein the first dopant comprises aluminum (Al), yttrium (Y), lanthanum (La), tantalum (Ta), niobium (Nb), or a combination thereof.

4. The semiconductor device according to claim 1,
wherein a thickness of the domain separation layer is in a range of 20% to 33% of a thickness of the dielectric layer.

5. The semiconductor device according to claim 1,
wherein a thickness ratio of the first ferroelectric layer, the domain separation layer, and the second ferroelectric layer is 1:1:1.

6. The semiconductor device according to claim 1,
wherein the domain separation layer has a crystal structure of a cubic crystal system or a tetragonal crystal system.

7. The semiconductor device according to claim 1,
wherein the dielectric layer has anti-ferroelectricity.

8. The semiconductor device according to claim 1,
wherein at least one of the first ferroelectric layer and the second ferroelectric layer contains a second dopant, and
wherein the second dopant comprises aluminum (Al), yttrium (Y), silicon (Si), lanthanum (La), or a combination thereof.

9. The semiconductor device according to claim 1,
wherein the first ferroelectric layer and the second ferroelectric layer comprise a same material.

10. The semiconductor device according to claim 1,
wherein each of the first ferroelectric layer and the second ferroelectric layer comprises hafnium oxide, hafnium zirconium oxide, or a combination thereof.

11. A semiconductor device comprising:
a substrate including an active region;
a lower electrode contact plug connected to the active region;
a lower electrode connected to the lower electrode contact plug;
an upper electrode disposed over the lower electrode; and
a dielectric layer disposed between the lower electrode and the upper electrode,
wherein the dielectric layer comprises:
a first ferroelectric layer;
a second ferroelectric layer disposed between the first ferroelectric layer and the upper electrode, the second ferroelectric layer having a domain different from a domain of the first ferroelectric layer; and
a domain separation layer disposed between the first ferroelectric layer and the second ferroelectric layer, the domain separation layer containing a first dopant and a metal element,
wherein the first dopant comprises a metal cation having a valency different from a valency of the metal element.

12. The semiconductor device according to claim 11,
wherein the domain separation layer comprises zirconium oxide, cerium oxide, or a combination thereof.

13. The semiconductor device according to claim 12,
wherein the first dopant comprises aluminum (Al), yttrium (Y), lanthanum (La), tantalum (Ta), niobium (Nb), or a combination thereof.

14. The semiconductor device according to claim 11,
wherein a thickness of the domain separation layer is in a range of 20% to 33% of a thickness of the dielectric layer.

15. The semiconductor device according to claim 11,
wherein a thickness ratio of the first ferroelectric layer, the domain separation layer, and the second ferroelectric layer is 1:1:1.

16. The semiconductor device according to claim 11,
wherein the domain separation layer has a crystal structure of a cubic crystal system or a tetragonal crystal system.

17. The semiconductor device according to claim 11,
wherein the dielectric layer has anti-ferroelectricity.

18. The semiconductor device according to claim 11,
wherein at least one of the first ferroelectric layer and the second ferroelectric layer includes a second dopant, and
wherein the second dopant comprises aluminum (Al), yttrium (Y), silicon (Si), lanthanum (La), or a combination thereof.

19. The semiconductor device according to claim 11,
wherein the first ferroelectric layer and the second ferroelectric layer comprise a same material.

20. The semiconductor device according to claim 11,
wherein each of the first ferroelectric layer and the second ferroelectric layer comprise hafnium oxide, hafnium zirconium oxide, or a combination thereof.
